(19) United States
(12) Patent Application Publication
(10) Pub. No.: US 2009/0001406 A1
(43) Pub. Date: Jan. 1, 2009

(54) Light-emitting device and method for fabricating same

(75) Inventor: Katsuyuki Okimura, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC LIGHTING, LTD., Tokyo (JP)

(21) Appl. No.: 12/149,274

(22) Filed: Apr. 29, 2008

(30) Foreign Application Priority Data
May 1, 2007 (JP) 2007-121075

(51) Int. Cl. H01L 33/00; H01L 21/02; H01R 43/00

(52) U.S. Cl. 257/99; 438/26; 29/825; 257/E21.002; 257/E33.066

(57) ABSTRACT

An LED chip is mounted on a submount, and submount electrodes are formed to constitute a submount member. A light-emitting unit is configured by mounting the submount member on a flat substrate. A lead frame member having a lead frame electrode is configured using a lead frame and a resin mold. A light-emitting device is obtained by overlapping the light-emitting unit and the lead frame member, so that the electrodes contact each other. There is accordingly obtained a light-emitting device that is highly reliable with respect to vibration, shock, and other external forces; that efficiently dissipates generated heat; and that is readily fabricated; and a method for fabricating same.

### BACKGROUND OF THE INVENTION

1. Field of the Invention

The present invention relates to a light-emitting device and a method for fabricating same, and particularly relates to a light-emitting device that has a cavity structure and a method for fabricating same.

2. Description of the Related Art

Existing light-emitting devices generally have a cavity structure shaped so that the intra-cavity diameter decreases from an aperture and toward a base. FIG. 1 is a top view showing a conventional light-emitting device. FIG. 2 is a cross-sectional view thereof. As shown in FIGS. 1 and 2, an LED (light-emitting diode) chip 11 mounted on a submount 12 is disposed on a base of a cavity 17 formed in a resin mold 32. Also disposed with the LED chip 11 on the submount 12 is a pair of submount electrodes 14a, 14b. The submount electrodes 14a, 14b are electrically connected to electrodes of the LED chip 11, by bonding wires 13a, 13b, respectively. The bonding wires 13a, 13b are electrically connected by bonding wires 51a and 51b, respectively, to a resin mold 32 (e.g., lead frame electrodes 52a, 52b formed by insert molding or another method). A heat sink 53 is disposed under the submount 12 so as to be electrically insulated against the lead frame electrodes 52a, 52b.

In the case of the conventional light-emitting device shown in FIGS. 1 and 2, the light-emitting element (LED chip 11) must be mounted on the base inside the cavity 17. When wiring is performed using an electroconductive wire, it is necessary to prevent interference between the wiring tool and the inner surface, and difficult work must therefore be performed.

As a means of solving such a problem, a technique is disclosed in Japanese Laid-Open Patent Application No. 2006-237141 (below, patent document 1) for placing, within a housing in which a lead frame has been insert-molded, a submount substrate wherein an LED chip is eutectically bonded to a silicon (Si) substrate and electrically connected using an electroconductive adhesive.

Japanese Laid-Open Patent Application No. 2003-46137 (Patent document 2) discloses a member created by mounting a semiconductor light-emitting element on a submount element, and a technique for performing bonding while electrically insulating a metal-plated reflecting wall from the electrode portion of the member. Although proposed as an anti-migration countermeasure, the technique also improves working efficiency when the device is fabricated.

However, the conventional techniques have problems such as those indicated below. For example, in the light-emitting device indicated in patent document 1, the submount substrate is placed within the housing, making it impossible to increase the area of the Si substrate that contributes to dissipate the heat of the LED chip. An electroconductive paste is used to hold together the submount substrate and the lead frame, and the lead frame portion is the fastening location when mounting on another printed-circuit board is performed to supply power to the device. When the present structure is subjected to vibration or shock, the stress applied to the light-emitting device is concentrated in the electroconductive paste. Therefore, the possibility of cracking or other adverse events in this portion cannot be discounted.

A method for fastening a submount element to a substrate that doubles as a reflector is not described in patent document 2, but the circumstances associated with the means disclosed in patent document 2 are the same as in the case of patent document 1. That is, when a vibration, shock or other external force is received, the stress is concentrated where both are joined, and the possibility of a crack or other problem cannot be discounted. In the light-emitting device of patent document 2, when considerable heat is generated by a light-emitting device, it is necessary to separately devise means for allowing heat generated by the LED to escape (e.g., to use a method for thermally connecting heat-dissipation means other than a submount element).

### SUMMARY OF THE INVENTION

An object of the present invention is to provide a light-emitting device that is highly reliable with respect to vibration, shock, and other external forces; efficiently dissipates generated heat; and is readily fabricated; and a method for fabricating the device.

The light-emitting device of the present invention comprises a substrate; one or a plurality of submounts disposed on the substrate; a light-emitting element and a submount electrode disposed on each submount; a resin mold having an aperture portion corresponding to the submount, at a location overlying the substrate and aligned with each submount; and a lead frame electrode that is supported so as to enter an interior of the aperture portion in the resin mold, and that contacts a submount electrode.

The present invention is configured so that a lead frame electrode and an electrode on the light-emitting element side on the submount contact each other within the aperture portion (cavity). This mitigates problems such as interference between an inner surface of the cavity and a wiring tool in a wiring operation, compared with that in a method that uses an electroconductive wire to connect a lead frame electrode and an electrode on the light-emitting element side, in the restricted space within a conventional cavity. Consequently, it becomes possible to readily implement wiring. By providing a submount on a substrate large enough to accommodate a lead frame member, the heat generated in a wire and a light-emitting element is efficiently transmitted to the substrate. Therefore, it is possible to improve the heat dissipation of a light-emitting device. By providing both a submount and a lead frame member on a substrate, the effect of vibration, shock or other external force on a light-emitting element or a wiring connection is diminished. This yields a light-emitting device that is highly reliable with respect to external forces.

In this case, the substrate preferably is a flat metallic substrate wherein the mounting surfaces for the resin mold and the submount are flat. This further improves the heat dissipation property described above.

For example, a bonding wire is used to connect an electrode of a light-emitting element and a submount electrode.

The lead frame electrode and submount electrode are preferably bonded using solder or a brazing material. This option is preferred because the stability of the electrode interconnection can be increased, and connecting can be performed more readily than in a connection method based on electroconductive wiring.

The inner surface of the aperture portion is preferably inclined relative to the substrate surface so that the aperture area increases as the distance from the substrate surface increases. The improved ease with which the wiring is performed, as described above, is particularly preferred in the case of a cavity structure (e.g., having the shape of a mortar), wherein the aperture area on the substrate side (base side of the cavity) decreases, and the aperture area on the side opposite the substrate increases. For example, a lead frame electrode extends from the inner surface of the aperture portion and is exposed within the aperture portion.

The resin mold can be configured so as to be smaller than the substrate and a mounting opening is formed in the area wherein the resin mold is provided on the substrate.

A concave portion preferably is formed in the substrate surface, at the position where the submount is disposed.

The above option allows the submount to be disposed in the concave portion and the overall height of the device to be reduced, when the mounted portion of the submount is high.

The method used to configure the light-emitting device of the present invention comprises the steps of: mounting a light-emitting element and a submount electrode on a submount, and obtaining a submount member; disposing one or a plurality of submount members on a substrate; and superimposing a resin mold on the substrate so that an aperture portion is aligned with the submount member, the resin mold having one or a plurality of aperture portions at locations aligned with the configuration in which the submount members are disposed, and having lead a frame electrode supported so as to extend from the inner surface of the aperture portion toward the interior of the aperture portion.

In the above method used to fabricate a light-emitting device, a metallic flat substrate having a flat surface for mounting the resin mold and the submount is preferably used as the substrate.

The lead frame electrode and the submount electrode preferably are bonded using solder or a brazing material.

According to the present invention, there is obtained a light-emitting device that is highly reliable with respect to vibration, shock, and other external forces; efficiently radiates generated heat; and can be fabricated readily; and a method for fabricating the device.

### BRIEF DESCRIPTION OF THE DRAWINGS

FIG. 1 is a top view showing a conventional light-emitting device;

FIG. 2 is a vertical cross-sectional view of the conventional light-emitting device shown in FIG. 1;

FIG. 3 is a top view showing a light-emitting device of an embodiment of the present invention;

FIG. 4 is a cross-sectional view showing a state wherein the light-emitting device of the embodiment of the present invention is installed in the intended device;

FIG. 5 is a top view showing a step for fabricating a light-emitting device of an embodiment of the present invention;

FIG. 6A is a top view showing the fabrication process subsequent to FIG. 5, and FIG. 6B is a cross-sectional view showing one of a plurality of sets of submount members shown in FIG. 6A;

FIG. 7A is a top view showing the fabrication process subsequent to FIGS. 6A and 6B, and FIG. 7B is a cross-sectional view showing one of a plurality of sets of lead frame members shown in FIG. 7A; and

FIG. 8A is a top view showing the fabrication process subsequent to FIGS. 7A and 7B, and FIG. 8B is a cross-sectional view showing one of a plurality of sets of light-emitting devices shown in FIG. 8A.

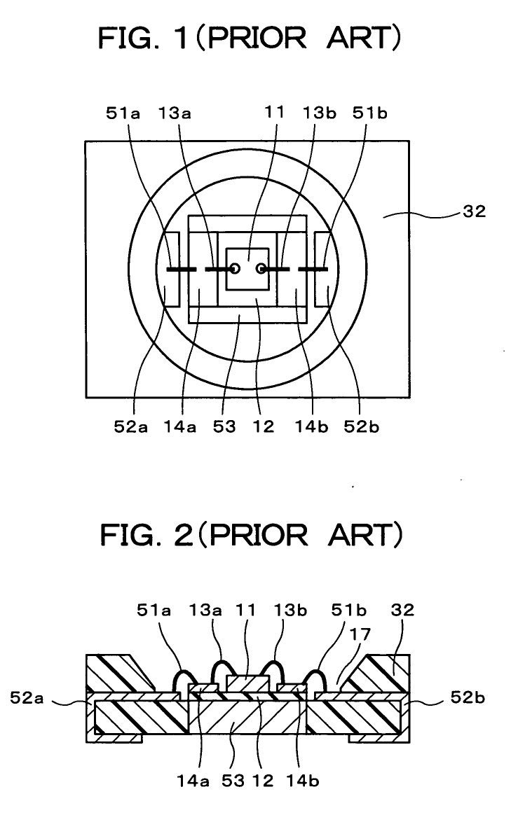

### DESCRIPTION OF THE PREFERRED EMBODIMENTS

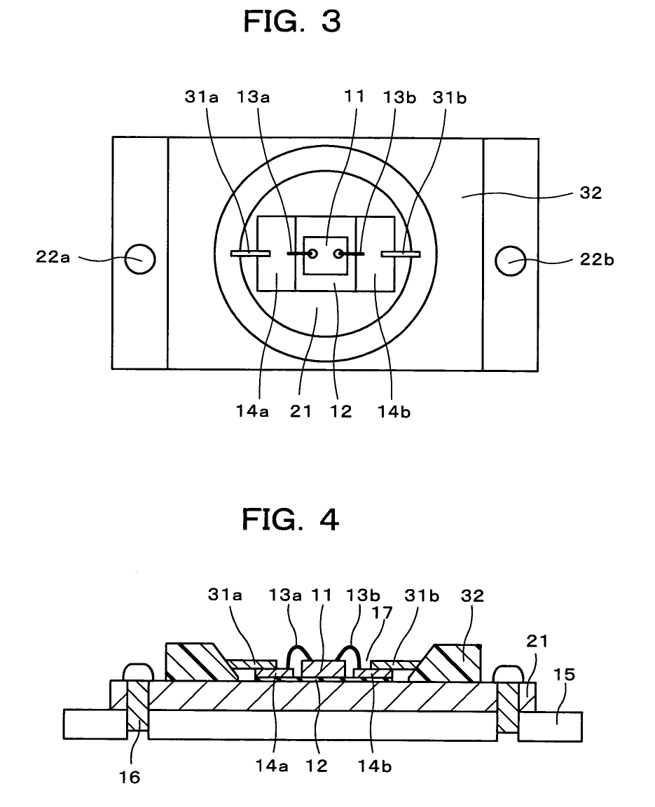

An embodiment of the present invention is next described in detail, with reference to the attached drawings. FIG. 3 is a top view showing the light-emitting device of the present embodiment, and FIG. 4 is a cross-sectional view showing a state wherein the light-emitting device of the present embodiment is installed on a target device.

As shown in FIGS. 3 and 4, a resin mold 32 is disposed on a flat substrate 21. A substrate created by forming an insulator on the surface of a metal base, for example, is used as the flat substrate 21. The resin mold 32 has an aperture portion (cavity 17), so that the area of the side contacting the flat substrate 21 decreases and the area on the side opposite the flat substrate 21 increases. The resin mold 32 includes a lead frame installed using insert molding or other method. In the manner described above, a lead frame member configured by integrating the lead frame and the resin mold 32 is fastened to the flat substrate 21, using, e.g., a screw. Parts of the lead frame are exposed toward the inside of the cavity 17, as lead frame electrodes 31a, 31b. The lead frame portions connected electrically with the exterior can be provided at any locations. However, an illustration thereof is omitted.

A submount 12 is disposed on the surface of the flat substrate 21, within the cavity 17. An LED chip 11 and submount electrodes 14a, 14b are provided to the submount 12. On the submount 12, at least the surface on which the submount electrodes 14a, 14b are disposed is electrically insulated. The submount electrodes 14a, 14b are electrically connected to the LED chip 11 by using bonding wires 13a, 13b, respectively. The submount electrode 14a and the lead frame electrode 31a as well as the submount electrode 14b and the lead frame electrode 31b are disposed so as to respectively contact each other and are electrically connected.

Mounting holes 22a, 22b are provided to the flat substrate 21. As shown in FIG. 4, the light-emitting device of the present embodiment is fastened to a target device 15, using mounting holes 22a, 22b and mounting screws 16, in the use mode. The target device 15 is a heat sink, external substrate, or the like. The mounting holes indicated by 22a and 22b in the drawing can be provided in any number, at any locations on the flat substrate 21.

Next, the operation of the present embodiment will be described. The heat generated while light is emitted from the LED chip 11 is successively transmitted from the LED chip 11 or the submount electrodes 14a, 14b, to the submount 12 and the flat substrate 21. The heat described above similarly is successively transmitted from the lead frame electrode 31b to the resin mold 32 and the flat substrate 21. In the present embodiment, a metal-base substrate with high thermal conductivity is used as the flat substrate 21. Therefore, the flat substrate 21 radiates heat efficiently. The flat substrate 21 is sufficiently larger than the areas of contact between the LED chip 11 and the submount electrodes 14a, 14b and the submount 12. This also promotes heat radiation. According to present embodiment, generated heat can be radiated efficiently.

In the present embodiment, as shown in FIG. 4, the submount 12 and the resin mold 32 are disposed on a common, metal-based flat substrate 21. According to such a configuration, vibration, shock, and other external forces applied from the exterior (target device 15) are transmitted to the flat substrate 21. However, because an external force is distributed, stress applied locally to the LED chip 11, a wiring connection, or the like is minimized. As a result, the reliability of the light-emitting device can be improved.

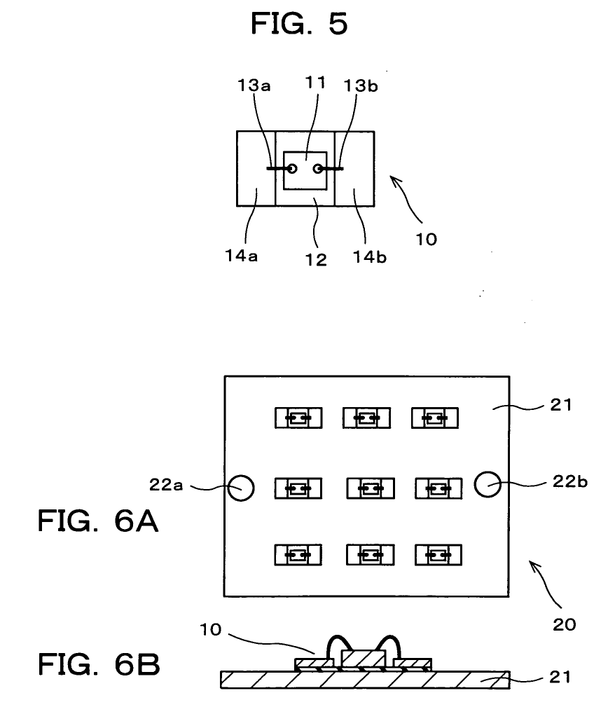

Next, the method used to fabricate the light-emitting device of the present embodiment described above will be described. FIGS. 5 through 8 are diagrams showing the method for fabricating the light-emitting device of the present embodiment, in a sequence of steps.

First, as shown in FIG. 5, the submount member 10 is fabricated. FIG. 5 is a top view showing the submount member 10. Initially, the LED chip 11 is mounted on the submount 12, and the submount electrodes 14a, 14b are formed. The LED chip 11 can be mounted using, e.g., eutectic bonding or other method. Next, the submount electrodes 14a, 14b are electrically connected to the LED chip 11 using the bonding wires 13a, 13b, respectively. The submount member 10 is accordingly obtained.

Next, as shown in FIGS. 6A and 6b, the light-emitting unit 20 is fabricated. FIG. 6A is a top view showing the state wherein a plurality of sets of submount members 10 is mounted on the flat substrate 21 and the light-emitting unit 20 is constructed. FIG. 6B is a cross-sectional view showing the state wherein one set of the submount parts 10 in FIG. 6A is mounted. Here, the submount part 10 is mounted on the flat substrate 21. A substrate created by forming an insulating layer on the surface of the submount part 10 side of a metal base is used as the flat substrate 21. In this case, mounting holes 22a, 22b leading to the device and the heat sink are created at arbitrary locations on the substrate, and the light-emitting unit 20 is accordingly obtained.

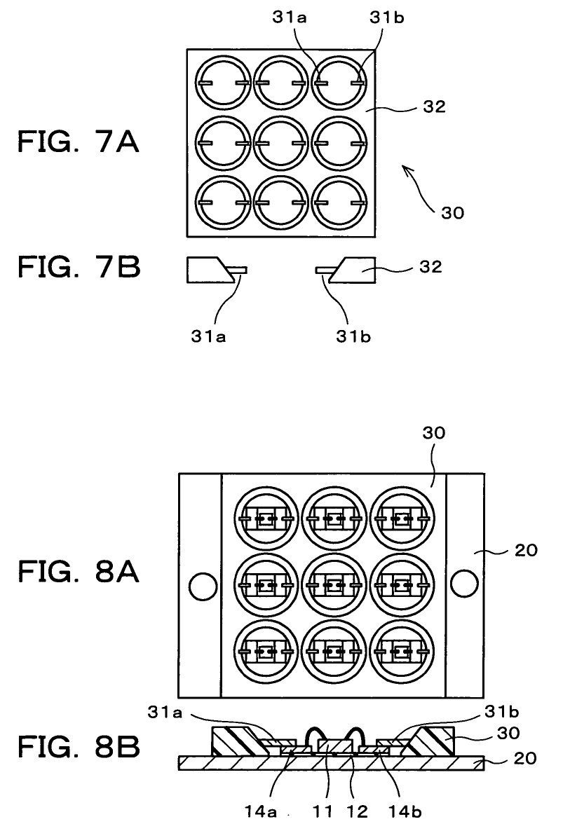

On the other hand, as shown in FIGS. 7A and 7B, the lead frame member 30 is fabricated separately from the light-emitting unit 20. FIG. 7A is a top view showing the state wherein multiple sets of aperture portions and lead frame electrodes 31a, 31b are formed in the lead frame member 30. FIG. 7B is a cross-sectional view showing one set of the aperture portion and lead frame electrodes 31a, 31b of FIG. 7A. Here, a resin mold is applied to the lead frame, and the lead frame member 30 is fabricated. Insert molding or another method, for example, can be used appropriately as the resin mold method. In FIG. 7 there is formed a plurality of aperture portions whose upper-side area increases and lower-side area decreases in FIG. 7B, relative to the resin mold 32. For one aperture portion, a pair of lead frame electrodes 31a, 31b is exposed, from the inner surface and toward the interior. For the lead frame, a portion that becomes an external electrode can be provided at any location and having any form. However, an illustration thereof is omitted. The resin mold 32 is to be sized so as not to conceal the mounting holes 22a, 22b provided in the flat substrate 21. The lead frame member 30 is accordingly obtained.

Next, as shown in FIGS. 8A and 8B, the light-emitting device is fabricated by stacking the light-emitting unit 20 and the lead frame member 30. FIG. 8A is a top view showing the state wherein multiple sets of light-emitting devices are integrally configured. FIG. 8B is a cross-sectional view showing one set of the light-emitting devices of FIG. 8B. Here, the lead frame member 30 is disposed on the light-emitting unit 20, so that the surface of the lead frame member 30 having the smaller aperture portion area contacts the surface on the side upon which is mounted the LED chip 11 of the light-emitting unit 20. In this case, in each set of light-emitting devices, the distal end positions of the lead frame electrodes 31a, 31b are made to contact the submount electrodes 14a, 14b, respectively. The lead frame member 30 can be fastened to the flat substrate 21, using, e.g., a setscrew. The light-emitting device of the present embodiment is accordingly obtained.

In the present embodiment, the light-emitting unit 20 upon which the submount member 10 is mounted and the lead frame member 30 are fabricated as separate units, which are stacked to fabricate a light-emitting device. In this case, the distal end positions of the lead frame electrodes 31a, 31b are made to contact the submount electrodes 14a, 14b, respectively, of the submount member 10 mounted on the light-emitting unit 20. As a result, the lead frame electrodes 31a, 31b and the submount electrodes 14a, 14b are electrically connected. In this manner, simply stacking two members completes the wiring of the submount electrodes 14a, 14b and the lead frame electrodes 31a, 31b. Using the method described above, the difficulties associated with conventional in-cavity wiring can be eliminated, and the number of man-hours required to wire a submount member 10 can be reduced.

In the present embodiment, it is possible to use solder or other brazing material when connecting the distal end positions of the electrodes (31a, 31b) of a lead frame member 30 and the electrode portions (14a, 14b) of a submount member 10 on the light-emitting unit 20. The stability of electrode interconnection is further increased thereby, and connecting can be performed more readily than in connection methods that use electroconductive wire. Therefore, the method described above is preferred. An electroconductive paste, for example, may be used at electrode interconnections.

In the present embodiment, the flat substrate 21 is used as the substrate. However, this arrangement is not provided by way of limitation in the present invention. For example, the flat electrode may be made concave, and the submount member 10 may be mounted at this location. In this manner, it is possible to reduce the overall device thickness.

What is claimed is:

1. A light-emitting device, comprising:
a substrate;
one or a plurality of submounts disposed on the substrate; a light-emitting element and a submount electrode disposed on each submount;
a resin mold having an aperture portion corresponding to the submount, at a location overlying the substrate and aligned with each submount; and
a lead frame electrode that is supported so as to enter an interior of the aperture portion in the resin mold, and that contacts a submount electrode.

2. The light-emitting device according to claim 1, wherein the substrate is a flat metallic substrate having flat surfaces for mounting the submount and the resin mold.

3. The light-emitting device according to claim 1, wherein bonding wire is used to connect the submount electrode and an electrode of the light-emitting element.

4. The light-emitting device according to claim 1, wherein solder or a brazing material is used to bond the lead frame electrode and the submount electrode.

5. The light-emitting device according to claim 1, wherein an inner surface of the aperture portion is inclined relative to the surface of the substrate, so that the aperture area increases as the distance from the surface of the substrate increases.

6. The light-emitting device according to claim 5, wherein the lead frame electrode extends from the inner surface of the aperture portion and is exposed within the aperture portion.

7. The light-emitting device according to claim 1, wherein the resin mold is smaller than the substrate and a mounting opening is formed in the area wherein the resin mold is provided on the substrate.

8. The light-emitting device according to claim 1, wherein a concave portion is formed at a position in the substrate surface where the submount is disposed.

9. A method for fabricating a light-emitting device, comprising the steps of:
mounting a light-emitting element and a submount electrode on a submount, and obtaining a submount member;
disposing one or a plurality of submount members on a substrate; and
superimposing a resin mold on the substrate so that an aperture portion is aligned with the submount member, the resin mold having one or a plurality of aperture portions at locations aligned with the configuration in which the submount members are disposed, and having lead frame electrodes supported so as to extend from the inner surface of the aperture portion toward the interior of the aperture portion.

10. The method for fabricating a light-emitting device according to claim 9, wherein a flat metallic substrate having flat surfaces for mounting the resin mold and the submount is used as the substrate.

11. The method for fabricating a light-emitting device according to claim 9, wherein solder or a brazing material is used to bond the lead frame electrode and the submount electrode.
